(19) United States
(12) Patent Application Publication
(10) Pub. No.: US 2025/0167472 A1
(43) Pub. Date: May 22, 2025

(54) CONNECTOR-BOARD ASSEMBLY, AND ELECTRONIC APPARATUS

(71) Applicant: Lenovo (Singapore) Pte. Ltd., Singapore (SG)

(72) Inventors: Munefumi Nakata, Kanagawa (JP); Osamu Ohsawa, Kanagawa (JP); Fumitake Mizoguchi, Kanagawa (JP)

(73) Assignee: Lenovo (Singapore) Pte. Ltd., Singapore (SG)

(21) Appl. No.: 18/917,084

(22) Filed: Oct. 16, 2024

(30) Foreign Application Priority Data
Nov. 17, 2023 (JP) 2023-196121

(51) Int. Cl. H01R 12/72; G06F 1/16; G06F 1/18; H01R 13/652; H01R 13/66; H01R 107/00

(52) U.S. Cl. CPC H01R 12/72; H01R 13/652; H01R 13/6675; H01R 13/6683; G06F 1/1616; G06F 1/183; H01R 2107/00; H01R 2201/06

(57) ABSTRACT

A connector-board assembly and an electronic apparatus detect damage to a receptacle connector. The connector-board assembly includes a receptacle connector and a board on which the receptacle connector is mounted. The receptacle connector has a tongue portion having electrodes at an approximately intermediate portion in a vertical direction of a plug insertion hollow portion. The tongue portion includes insulating layers provided above and below a metal plate and includes the electrodes on the surfaces of the insulating layers. The metal plate includes a first portion and a second portion which extend from a base end side toward an opening side and are electrically conductive to each other on the opening side. The first portion is connected to a signal input port on the board and connected to a power supply via a pull-up resistor. The second portion is connected to the ground.

### CROSS-REFERENCE TO RELATED APPLICATIONS

This application claims priority to Japanese Patent Application No. 2023-196121 filed on Nov. 17, 2023, the contents of which are hereby incorporated herein by reference in their entirety.

### BACKGROUND OF THE INVENTION

### Field of the Invention

The present invention relates to a connector-board assembly having a receptacle connector and a board mounted with the receptacle connector, and an electronic apparatus.

### Description of the Related Art

A laptop or tablet PC has a receptacle connector on the side of a flat-shaped chassis. The receptacle connector is often mounted on the edge of a motherboard. The receptacle connector may have a tongue portion equipped with electrodes at an approximately intermediate portion in the vertical direction in a plug insertion hollow portion (Japanese Unexamined Patent Application Publication No. 2019-36484).

### SUMMARY OF THE INVENTION

However, when an excessive force beyond that expected is applied to the receptacle connector, the tongue portion is damaged and the functions of the motherboard related to the receptacle connector (such as a charging function) are disabled. When it is difficult to identify the location of a failure by visual inspection, etc., the motherboard itself will need to be replaced, thereby resulting in the concern that a cost burden on a user increases.

Embodiments of the present invention provide a connector-board assembly and an electronic apparatus capable of detecting damage to a receptacle connector.

Embodiments of the present invention include a connector-board assembly according to a first aspect of the present invention, which includes a receptacle connector and a board on which the receptacle connector is mounted. The receptacle connector has a tongue portion having electrodes at an approximately intermediate portion in a vertical direction of a plug insertion hollow portion. The tongue portion has a first ground level conductor and a second ground level conductor which extend from a base end side toward an opening side of the receptacle connector and are electrically conductive to each other on the opening side. The first ground level conductor is connected to a signal input port of a detection determining unit in the board and connected to a power supply via a pull-up resistor. The second ground level conductor is connected to the ground.

An electronic apparatus according to a second aspect of the present invention includes a receptacle connector and a board on which the receptacle connector is mounted. The receptacle connector has a tongue portion having electrodes at an approximately intermediate portion in a vertical direction of a plug insertion hollow portion. The tongue portion has a first ground level conductor and a second ground level conductor which extend from a base end side toward an opening side of the receptacle connector and are electrically conductive to each other on the opening side. The first ground level conductor is connected to a signal input port of a detection determining unit in the board and connected to a power supply via a pull-up resistor, and the second ground level conductor is connected to the ground on the board.

According to the above-described aspects of present invention, it is possible to detect damage to a receptacle connector.

### BRIEF DESCRIPTION OF THE DRAWINGS

FIG. 1 is a perspective view of a laptop PC according to an embodiment of the present invention;

FIG. 2 is a schematic perspective view of a receptacle connector;

FIG. 3 is a cross-sectional side view of the receptacle connector;

FIG. 4 is a cross-sectional view taken along line IV-IV in FIG. 3;

FIG. 5 is a view of the receptacle connector as viewed from the outside;

FIG. 6 is a bottom view of the receptacle connector;

FIG. 7 is a schematic cross-sectional view of the receptacle connector;

FIG. 8 is a view illustrating a metal plate and a part of an electric circuit in a board to which the metal plate is connected;

FIGS. 9A to 9C are schematic cross-sectional views of the tip of a tongue portion in a receptacle connector according to a first modification, in which FIG. 9A is a view illustrating a normal time of the receptacle connector, FIG. 9B is a view illustrating a first abnormal state thereof, and FIG. 9C is a view illustrating a second abnormal state thereof;

FIG. 10 is a schematic cross-sectional view of a receptacle connector according to a first modification;

FIG. 11 is a view illustrating a bottom surface of the receptacle connector according to the first modification, and a part of an electric circuit in a board to which the receptacle connector is connected;

FIG. 12 is a view illustrating a bottom surface of a receptacle connector according to a second modification, and a part of an electric circuit in a board to which the receptacle connector is connected; and

FIG. 13 is a schematic cross-sectional view of the tip of a tongue portion in the receptacle connector according to the second modification.

### DETAILED DESCRIPTION OF THE INVENTION

Hereinafter, embodiments of a connector-board assembly and an electronic apparatus according to the present invention will be described in detail with reference to the accompanying drawings. Note that the present invention is not limited by the embodiments.

Examples of the connector-board assembly and the electronic apparatus according to the embodiments of the present invention will hereinafter be described in detail with reference to the accompanying drawings. Note that the present invention is not limited by the examples.

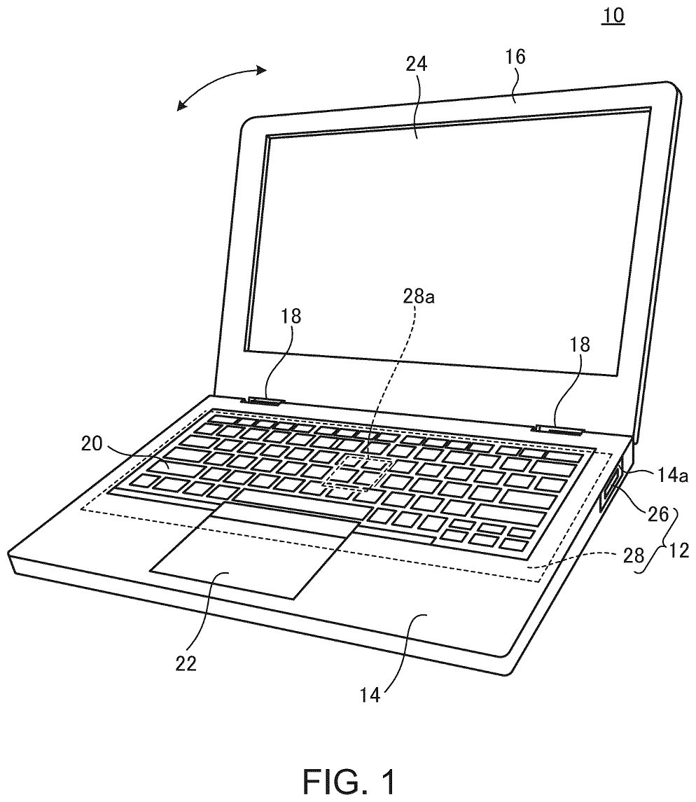

FIG. 1 is a perspective view of a laptop PC (electronic apparatus) 10 which serves as an electronic apparatus according to an embodiment of the present invention. The laptop PC10 includes a connector-board assembly 12 according to the embodiment of the present invention. The connector-board assembly 12 is incorporated inside a chassis 14 of the laptop PC10. The electronic apparatus according to the present invention is not limited to the laptop PC10 and may be, for example, a desktop PC or a mobile tablet terminal or the like.

The laptop PC10 includes a lid 16 which can be opened and closed by hinges 18 with respect to the chassis 14. The laptop PC 10 becomes compact by closing the lid 16 and is suitable for mobile use.

The chassis 14 is provided with a keyboard device 20 and a touch pad 22. A display device 24, which occupies most of the area of the front surface of the lid 16, and a speaker and a camera which are not illustrated in the drawing are provided on the front side of the lid 16.

The connector-board assembly 12 is incorporated into the chassis 14. The connector-board assembly 12 includes a receptacle connector 26 and a board 28. The board 28 serves as a main board in the laptop PC10 and is provided inside the chassis 14 across almost both left and right ends thereof. A CPU (detection determining unit) 28a which controls the entire laptop PC10 is mounted on the board 28. In the connector-board assembly 12, the board 28 on which the receptacle connector 26 is mounted may be a sub-board separate from the main board. The receptacle connector 26 is of a so-called top mount type with respect to one surface of the board 28, but may be attached by a so-called mid-mount type in which it fits into a notch formed in the board 28. The mounting form of the receptacle connector 26 on the board 28 is not limited to soldering, but may be a detachable pin contact type or the like.

For convenience of description, the side of the chassis 14 is defined as the outside around the receptacle connector 26, and conversely, the interior of the chassis 14 is defined as the inside. Further, on the basis of the board 28, the side on which the majority of components are mounted is defined as the top, and its opposite side is defined as the bottom. The reference for the top and bottom may be opposite to that of the chassis 14, with the side on which the keyboard device 20 is provided being the bottom. These directional names are given for the convenience of description, and the invention is not limited to this.

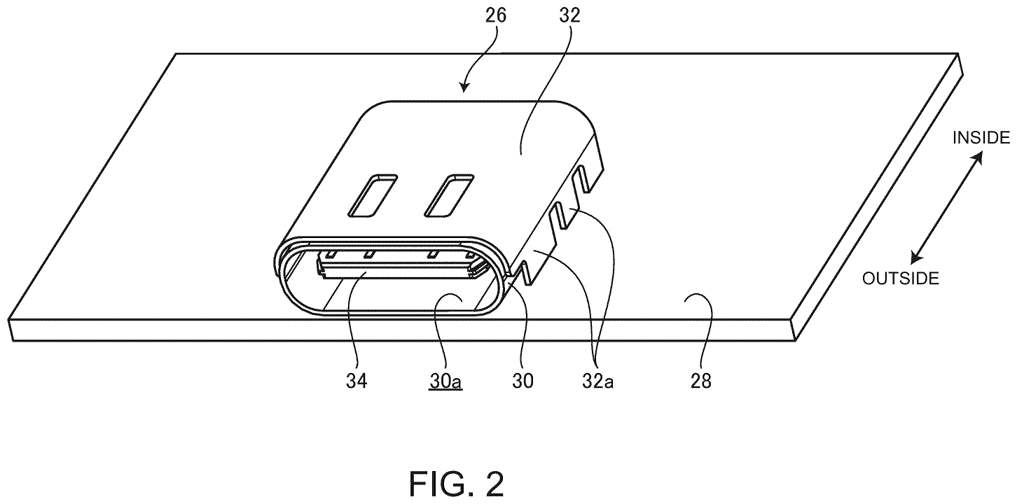

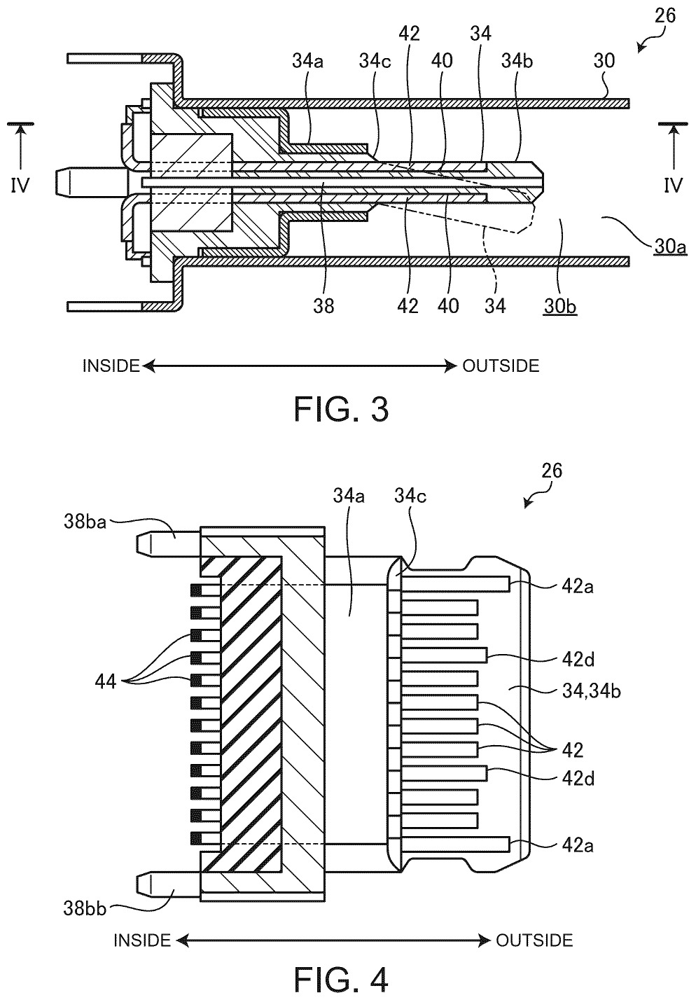

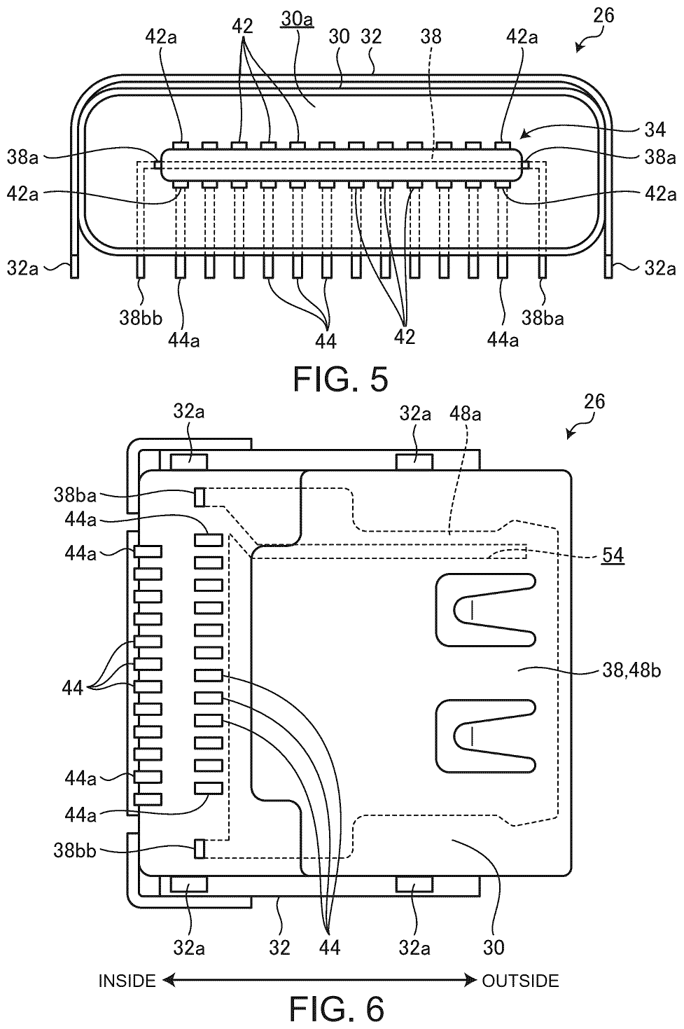

FIG. 2 is a schematic perspective view of the receptacle connector 26. FIG. 3 is a cross-sectional view of the receptacle connector 26. FIG. 4 is a cross-sectional view taken along line IV-IV in FIG. 3. FIG. 5 is a view of the receptacle connector 26 as viewed from the outside (opening side).

The receptacle connector 26 is, for example, a small connector called a standardized USB Type C, and is used for data transmission or charging. The receptacle connector 26 may be HDMI (High-Definition Multimedia Interface, registered trademark) or the like. The receptacle connector 26 is configured based on a flat plug holding cylindrical body 30 with rounded corners. The plug holding cylindrical body 30 is generally made of metal. A connector hole 14a (refer to FIG. 1) is formed in a side surface of the chassis 14, and a plug insertion opening 30a of the plug holding cylindrical body 30 is exposed from the connector hole 14a. A plug connector (abbreviated in the figure) is inserted and connected into a plug insertion hollow portion 30b corresponding to the inside of the plug insertion opening 30a. The plug connector can be inserted upside down. The plug holding cylindrical body 30 is mounted in a state in which a lower surface thereof is placed on an upper surface of the board 28, and has side and upper surfaces covered with a metal shell 32. The shell 32 is flattened and horseshoe-shaped, and is mounted on the board 28. The shell 32 is substantially integrated with the plug holding cylindrical body 30 and is taken to be part of the receptacle connector 26. The plug holding cylindrical body 30 and the shell 32 are electrically conducted to the ground of the board 28 and have electromagnetic shielding action.

The receptacle connector 26 has a tongue portion 34 at an approximately intermediate portion in a vertical direction of the plug insertion hollow portion 30b of the plug holding cylindrical body 30. The tongue portion 34 is formed into a plate shape, and extends from an inner mold base 36 of the receptacle connector 26 to the outside inside the plug holding cylindrical body 30. When viewed from the outside (refer to FIG. 5), the tongue portion 34 has nearly equal gaps from the top, bottom, left and right walls of the plug holding cylindrical body 30. The tongue portion 34 has an outer tip portion 34b which is slightly thinner than an inner base portion 34a (refer to FIG. 3) and has an inclined step 34c formed between them. The tip of the tongue portion 34 is located slightly inside an outer end of the plug holding cylindrical body 30.

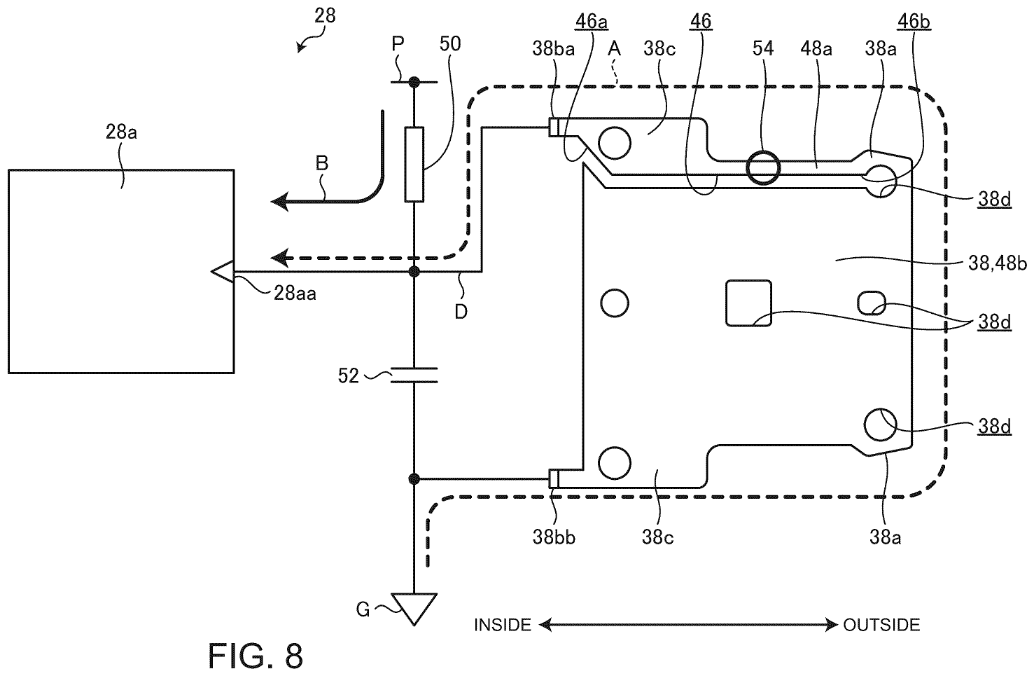

A metal plate 38 is provided at a vertical intermediate portion of the tongue portion 34. Insulating layers 40 each made of a resin material are provided above and below the metal plate 38. The metal plate 38 and the upper and lower insulating layers 40 have approximately the same thickness. Both outer ends 38a of the metal plate 38 are slightly exposed from the insulating layers 40 and are adapted to come into contact with ground terminals of the plug connector. Both inner ends of the metal plate 38 form two mounting terminals 38ba and 38bb (refer also to FIG. 6). The mounting terminals 38ba and 38bb are bent downward at their inner portions. The mounting terminal 38ba is electrically connected to a detection line D (refer to FIG. 8) of the board 28, and the mounting terminal 38bb is electrically connected to the ground G (refer to FIG. 8) of the board 28.

The tongue portion 34 is provided with a plurality of electrodes 42. The electrodes 42 are exposed on the upper and lower surfaces of the tip portion 34b and are adapted to come into contact with electrodes of the plug connector. In the present embodiment, a total of twenty-four electrodes 42 are provided twelve above and twelve below the tip portion 34b. Each electrode 42 passes through the base portion 34a and is bent downward inside the mold base 36 with its lower end forming a mounting terminal 44 electrically connected to the board 28.

FIG. 6 is a bottom view of the receptacle connector 26. The mounting terminals 44 are arranged in two rows slightly offset in inner and outer directions. Of these, the mounting terminals in the outer row are connected to a lower surface of the tongue portion 34, and the mounting terminals in the inner row are connected to an upper surface of the tongue portion 34. The inner row and the outer row are slightly offset in the vertical direction on the paper of FIG. 6. Of the mounting terminals 44, a total of four at each end of the inner and outer rows are ground terminals 44a and are electrically connected to the ground of the board 28. Each ground terminal 44a is connected to a ground electrode 42a.

Four mounting terminals 32a protrude from a lower edge of the shell 32 and are electrically connected to the ground of the board 28. The plug holding cylindrical body 30 is in contact with the shell 32 and has the same electrical potential as the shell 32. Incidentally, the mounting terminal 32a, the mounting terminal 38bb, and the ground terminal 44a which are at the ground level are not connected to each other inside the receptacle connector 26, but are connected via the ground of the board 28.

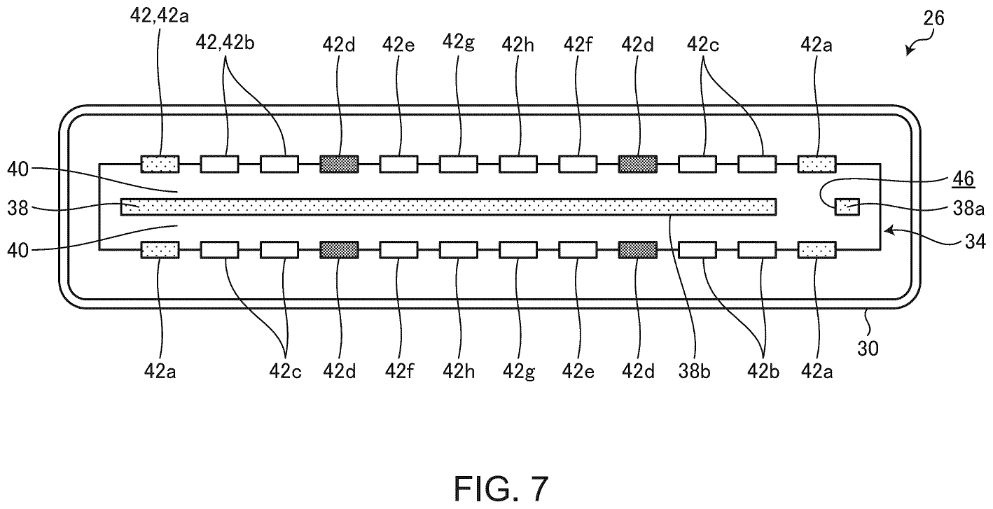

FIG. 7 is a schematic cross-sectional view of the receptacle connector 26. The electrodes 42 are provided in two states above and below the tongue portion 34, and both ends of each stage are the ground electrodes 42a. The ground electrode 42a and the metal plate 38 are indicated by light dots. The ground electrode 42a is longer than the other electrodes (refer to FIG. 4). The two electrodes adjacent to each of the ground electrodes 42a on the upper left side and the lower right side are high-speed transmission electrodes 42b. The two electrodes adjacent to each of the ground electrodes 42a on the upper right side and the lower left side are high-speed reception electrodes 42c. A power supply electrode 42d is provided to be located inwardly of each of the high-speed transmission electrode 42b and the high-speed reception electrode 42c. The power supply electrode 42d is indicated by a dark dot. The power supply electrode 42d is shorter than the ground electrode 42a and longer than the other electrodes 42 (refer to FIG. 4). The electrode adjacent to each of the power supply electrodes 42d on the upper left side and the lower right side is a plug orientation detection electrode 42e. The electrode adjacent to each of the power supply electrodes 42d on the upper right and lower left sides is an extension electrode 42f. The electrode adjacent to each of the plug orientation detection electrodes 42e on the upper left and lower right sides is a low-speed transmission electrode 42g. The electrode adjacent to each of the extension electrodes 42f on the upper right and lower left sides is a low-speed reception electrode 42h.

The high-speed transmission electrode 42b and the high-speed reception electrode 42c are electrodes which form a pair of signals for communication. The low-speed transmission electrode 42g and the low-speed reception electrode 42h are electrodes which form a pair of signals for communication. The communication through the high-speed transmission electrode 42b and the high-speed reception electrode 42c is faster than the communication through the low-speed transmission electrode 42g and the low-speed reception electrode 42h. In other words, the high-speed transmission electrode 42b and the high-speed reception electrode 42c are the highest speed signal line electrodes in the receptacle connector 26.

The high-speed transmission electrodes 42b, high-speed reception electrodes 42c, plug orientation detection electrodes 42e, extension electrodes 42f, low-speed transmission electrodes 42g, and low-speed reception electrodes 42h at the upper and lower stages are surrounded by the plug holding cylindrical body 30 at the ground potential and the ground electrodes 42a and provide little electromagnetic leakage. Further, the upper and lower stages are separated by the metal plate 38, so that there is little mutual interference. The metal plate 38 also acts to secure the strength of the tongue portion 34. The high-speed transmission electrode 42b and the high-speed reception electrode 42c are more likely to generate noise than the low-speed transmission electrode 42g and the low-speed reception electrode 42h, but are located at positions where they are sandwiched between the ground electrode 42a and the power supply electrode 42d on both sides thereof, so that there is little electromagnetic leakage.

FIG. 8 is a view illustrating the metal plate 38 and a part of an electric circuit in the board 28 to which the metal plate 38 is connected. The metal plate 38 is substantially square, but the inner ends 38c protrude expansively on both sides, and the outer ends 38a protrude slightly. A plurality of holes 38d provided in the metal plate 38 are for integrally molding with the insulating layers 40 (refer to FIG. 3). The metal plate 38 has the inner ends 38c arranged inside the base end 34a (refer to FIG. 3), and portions other than those are arranged inside the tip portion 34b. The mounting terminals 38ba and 38bb are connected to the ends of the inner ends 38c. The mounting terminal 38ba is assumed to be connected to one of the two inner ends 38c on the upper side of the paper in FIG. 8, and the mounting terminal 38bb is assumed to be connected to the other thereof on the lower side of the paper.

The metal plate 38 is formed with a thin slit-like notch 46 which extends inwardly and outwardly and is open to the inside. The notch 46 is located toward the upper side of the paper in FIG. 8, and divides the metal plate 38 into an upper narrow first portion (first ground level conductor) 48a and a lower wide second portion (second ground level conductor) 48b. The first portion 48a is slightly wider at a location where it is formed at the inner end 38c, but is narrow at a location on the outer side thereof. An inner end 46a of the notch 46 is inclined at about 45° so as to lean upward toward the inside. An outer end 46b of the notch 46 is in communication with one of the holes 38d. Since the metal plate 38 is cut out from a plate material in single punching processing inclusive of the notch 46 and the holes 38d, no additional processing is required to form the notch 46 and the holes 38d, and there is almost no increase in costs.

The first portion 48a and the second portion 48b each extend from the base end side toward the plug insertion opening 30a side (outside) and are in electrical conduction with each other at their outer portions. Since the mounting terminal 38bb is connected to the ground G, the first portion 48a and the second portion 48b are each normally at a zero potential, i.e., at the ground level.

The first portion 48a is connected to a signal input port 28aa of the CPU 28a on the board 28 via the mounting terminal 38ba and the detection line D, and is connected to a power supply P via a pull-up resistor 50. Further, a capacitor 52 is provided between the detection line D and the ground G. The signal input port 28aa is, for example, a GPIO (General-purpose input/output), which detects an input voltage as 0 when it is at the ground G level and as 1 when it is at the power supply P level. Since the capacitor 52 short-circuits the first portion 48a and the ground G with respect to the AC component, it acts as a ground return for high-speed noise superimposed on the first portion 48a.

Since the first portion 48a is normally at the ground level, as indicated by an arrow A, the CPU 28a detects “0” and recognizes that the receptacle connector 26 is normal. On the other hand, when an excessive force beyond expectations is applied to the receptacle connector 26 via the plug connector or the like, the tongue portion 34 may be damaged. For example, it may be bent at the step 34c as indicated by an imaginary line in FIG. 3. In that case, there is a concern that the first portion 48a which is much thinner than the second portion 48b in the metal plate 38, may be cut. An example of a portion where there is a risk of its cutting is illustrated schematically by reference numeral 54.

When the first portion 48a is cut at the portion indicated by the reference numeral 54, the electrical conduction with the second portion 48b is lost, so that the potential of the detection line D becomes the same as that of the power supply P via the pull-up resistor 50. Therefore, as indicated by an arrow B, the CPU 28a can detect “1” and detect damage to the receptacle connector 26.

Incidentally, assuming that the first portion 48a and the second portion 48b are the same in thickness, neither thereof is cut and there is also a possibility that an abnormality cannot be detected. However, by setting the first portion 48a and the second portion 48b to different thicknesses as in the present embodiment, the thinner side is cut, thereby making is possible to detect an abnormality. It is conceivable that the metal plate 38 will be cut at the thin first portion 48a, but even when it is cut at the thick second portion 48b or at the boundary portion between the first portion 48a and the second portion 48b, it is possible to detect the cutting in like manner. For the first portion 48a and the second portion 48b, the electromagnetic shielding effect may be maintained by making the second portion 48b directly connected to the ground G relatively thicker than the first portion 48a.

When the signal detected at the signal input port 28aa is “1”, the CPU 28a performs a display such as “connector abnormality” on the display device 24 to notify the user or worker of it. Further, when the signal detected at the signal input port 28aa is “0”, the CPU 28a does not need to take any particular action, but may perform a display such as “connector normal” on the display device 24 depending on the specifications. The CPU 28a basically always checks for abnormalities in the receptacle connector 26 via the signal input port 28aa, but it may perform the check for it when the system is started, at a predetermined interval time, or at a predetermined timing (for example, when the user requests the investigation of abnormality). The detection of the state of the detection line D is not necessarily limited to digital processing by software, but may be performed by an analog circuit to sound a beep tone or light a lamp.

Further, there may be a case where the cutting of only the thin first portion 48a causes almost no hindrance to the electrical function of the receptacle connector 26, and charging, communication, and the like can be continued. In particular, when the detection by the signal input port 28aa is not always “1”, but is approximately “0” and rarely becomes “1”, “caution of connector”, “check connector”, or the like may be displayed instead of “connector abnormality” depending on the judgement of the CPU 28a.

When the charging or communication is not possible via the receptacle connector 26 in the laptop PC10, the user or worker is able to specify the location of a failure if “connector abnormality” is displayed on the display device 24, and can adjust and repair the receptacle connector 26 in a focused way. Further, it is no longer necessary to replace a relatively expensive motherboard itself by replacing the receptacle connector 26, thereby making it possible to reduce a cost burden on the user.

Return to FIG. 7. The notch 46 is formed thin enough so as not to reduce the action of the metal plate 38 as the ground. In the present embodiment, it is formed in the range from the right ends of the high-speed transmission electrode 42 and the high-speed reception electrode 42c to the right end of the ground electrode 42a in FIG. 7. When viewed in the surface normal direction (viewed in the vertical direction on the paper in FIG. 7) of the tongue portion 34, the notch 46 at least partially overlaps with the upper and lower ground electrodes 42a. Further, although the metal plate 38 does not exist in the notch 46 portion, the upper and lower ground electrodes 42a complement the electromagnetic leakage effect appropriately. Even if the notch 46 is positioned so that it overlaps partially or entirely with the power supply electrode 42d, the power supply electrode 42d functions to prevent electromagnetic leakage.

That is, when viewed in the surface normal direction of the tongue portion 34, the notch 46 is formed along the high-speed transmission electrode 42b and the high-speed reception electrode 42c being the highest speed signal line electrodes among the electrodes 42, so as not to overlap them. This prevents the notch 46 from dividing the metal plate 38 at the points facing the high-speed transmission electrode 42b and the high-speed reception electrode 42c, and ensures a path (return path) for a return current of a high-frequency signal as appropriate, thereby enabling a reduction in noise. When the notch 46 overlaps with the high-speed signal electrodes 42b and 42c, there is a concern that a return loss may deteriorate. Therefore, if a certain degree of width is required for processing reasons, etc., the notch 46 may be positioned so that it overlaps with the ground electrode 42a. Further, noise generated in the vertical direction by the high-speed transmission electrode 42b and the high-speed reception electrode 42c is blocked by the plug holding cylindrical body 30 or the metal plate 38. Furthermore, the metal plate 38 separates between the high-speed transmission electrode 42b and the high-speed reception electrode 42c, thereby making it possible to prevent mutual interference.

Next, a receptacle connector 26A according to a first modification and an electric circuit according to the receptacle connector 26A will be described.

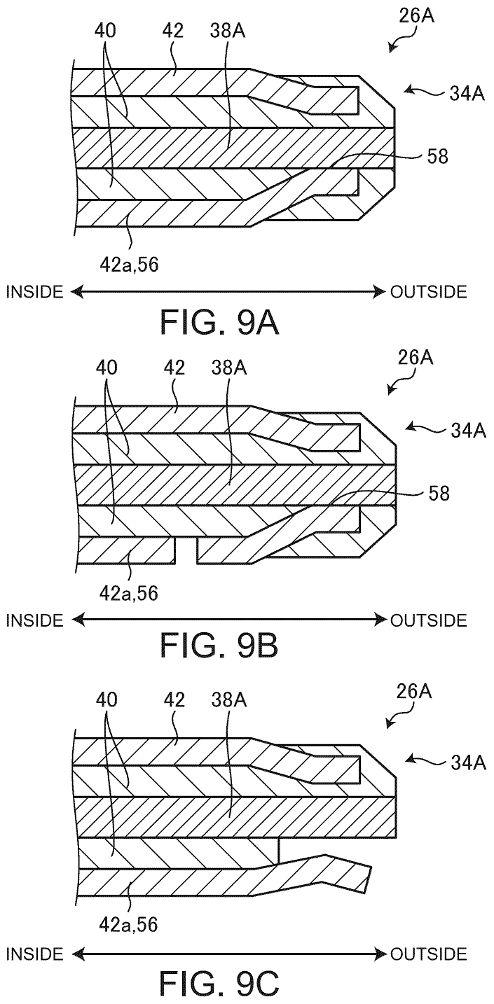

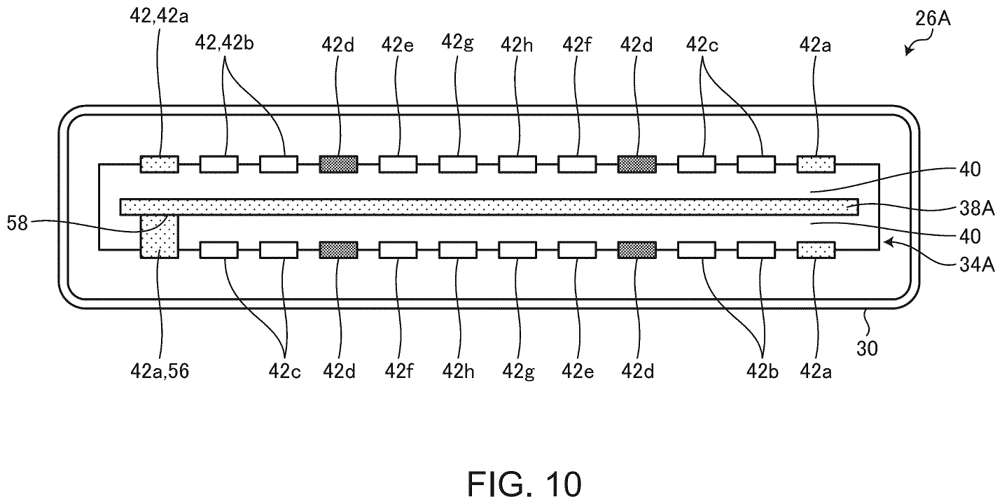

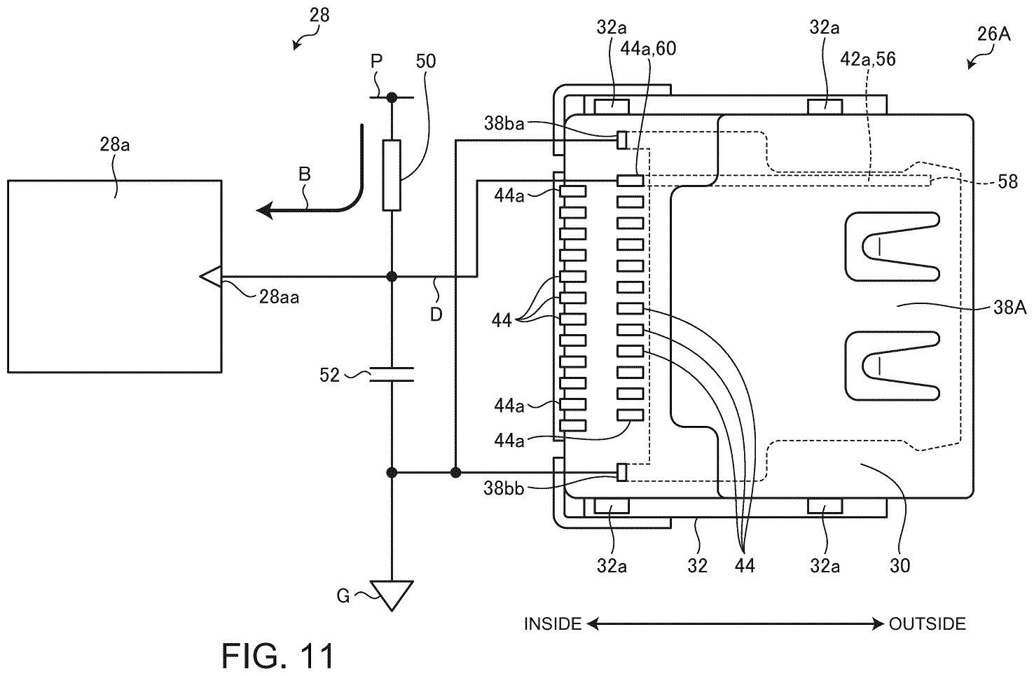

FIGS. 9A to 9C are schematic cross-sectional views of the tip of a tongue portion 34A in the receptacle connector 26A, in which FIG. 9A is a view illustrating a normal time of the receptacle connector, FIG. 9B is a view illustrating a first abnormal state thereof, and FIG. 9C is a view illustrating a second abnormal state thereof. FIG. 10 is a schematic cross-sectional view of the receptacle connector 26A. FIG. 11 is a view illustrating a bottom surface of the receptacle connector 26A, and a part of an electric circuit in a board 28 to which the receptacle connector 26A is connected. In the description of the receptacle connector 26A, the same components as those of the receptacle connector 26 are given the same reference numerals, and their detailed description will be omitted.

The receptacle connector 26A has a tongue portion 34A and a metal plate 38A corresponding to the above-described tongue portion 34 and metal plate 38. The metal plate (second ground level conductor) 38A does not have the notch 46 in the metal plate 38 described above. In the tongue portion 34A, one of four ground electrodes 42a is used as an abnormality detection electrode (first ground level conductor) 56. A tip portion of the abnormality detection electrode 56 is in contact with and electrically conductive to the metal plate 38A as a contact portion 58. In other words, the tongue portion 34A has the abnormality detection electrode 56 and the metal plate 38A which extend from the base end side toward the opening side and are electrically conductive to each other on the opening side. The abnormality detection electrode 56 is connected to a signal input port 28aa and is connected to a power supply P via a pull-up resistor 50, and the metal plate 38A is connected to the ground G.

As illustrated in FIG. 9A, the tip of an electrode 42 is inclined outwardly so as to approach the metal plate 38. This portion is covered and protected by a part of an insulating layer 40. A tip portion of the abnormality detection electrode 56 is inclined until it comes into contact with the metal plate 38 to form the contact portion 58. The contact portion 58 is formed by pressure welding or welding or the like and is integrally molded with the insulating layer 40 for protection. The abnormality detection electrode 56 is sufficiently thin compared to the metal plate 38.

In the receptacle connector 26A, a mounting terminal 38bb is electrically connected to the ground G (refer to FIG. 11) in the same manner as in the above example. Further, a mounting terminal 38ba is also connected to the ground G.

In the receptacle connector 26A, an abnormality detection terminal 60 which is connected to the abnormality detection electrode 56 and is one of four ground terminals 44a, is connected to a detection line D. Therefore, in the receptacle connector 26A, the abnormality detection electrode 56 has the same function as the first portion 48a in the above example. That is, as illustrated in FIG. 9B, when the abnormality detection electrode 56 is cut off midway, electrical conduction with the metal plate 38 is lost, so that the potential of the detection line D becomes the same as that of the power supply P via the pull-up resistor 50. Therefore, as indicated by an arrow B, a CPU 28a detects “1” and is capable of detecting damage to the receptacle connector 26A.

Although the tip of the electrode 42 is covered and protected by the insulating layer 40, it is conceivable that when unexpected strong stress is applied thereto where a plug connector is inserted or extracted, the resin may peel off as illustrated in FIG. 9C. In this case, since the tip of the abnormality detection electrode 56 is exposed and separated from the metal plate 38, and electrical conduction with the metal plate 38 is lost, it is possible to detect damage to the receptacle connector 26A in the same manner as in the case of FIG. 9B.

Next, a receptacle connector 26B according to a second modification and an electric circuit according to the receptacle connector 26B will be described.

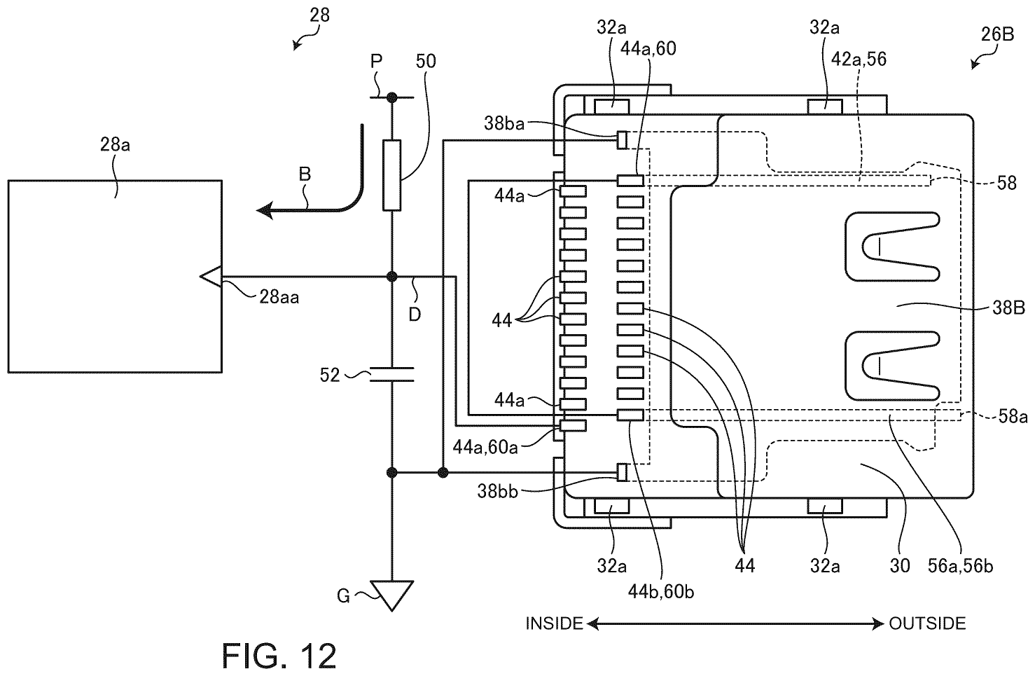

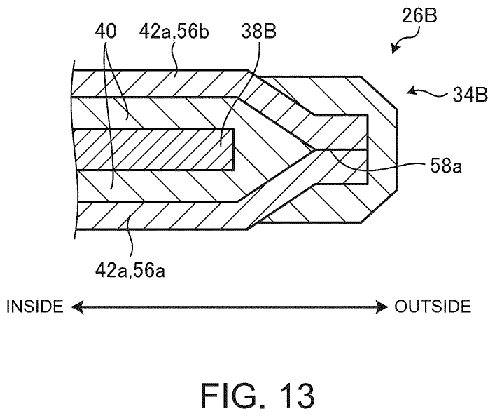

FIG. 12 is a view illustrating a bottom surface of the receptacle connector 26B and a part of an electric circuit in a board to which the receptacle connector 26B is connected. FIG. 13 is a schematic cross-sectional view of the tip of a tongue portion 38B in the receptacle connector 26B.

The receptacle connector 26B has a tongue portion 34B and a metal plate 38B corresponding to the above-described tongue portion 34 and metal plate 38. In the tongue portion 34B, one of four ground electrodes 42a is used as an abnormality detection electrode 56 similar to that described above. Further, the other two are used as abnormality detection electrodes 56a and 56b. The abnormality detection electrode 56 and the abnormality detection electrodes 56a and 56b are on opposite sides. As illustrated in FIG. 13, the tips of the abnormality detection electrodes 56a and 56b are in contact with each other at a contact portion 58a. The contact portion 58a is not in contact with the metal plate 38B.

In the receptacle connector 26B, an abnormality detection terminal 60a among four ground terminals 44a, which is connected to the abnormality detection electrode 56a, is connected to a detection line D. Further, an abnormality detection terminal 60b connected to the abnormality detection electrode 56b is connected to the abnormality detection electrode 56. In other words, the abnormality detection electrodes 56, 56a, and 56b are connected in series. Using such a receptacle connector 26B electrical conduction with the metal plate 38 is lost when any of the three abnormality detection electrodes 56, 56a, and 56b is cut off in the middle. Therefore, the potential of the detection line D becomes the same as that of the power supply P via a pull-up resistor 50. This improves the accuracy of detecting an abnormality.

The four ground electrodes 44a may each be used as the abnormality detection electrode, and a signal may be read at a signal input port 28aa via a four-input one-output OR circuit. Further, four signal input ports 28aa may be prepared and signals may be read individually.

The present invention is not limited to the above-described embodiments, and can of course be freely modified within the scope not departing from the spirit of the present invention.

### DESCRIPTION OF SYMBOLS

10 laptop PC
12 connector-board assembly
26, 26A receptacle connector
28 board
28aa signal input port
30 plug holding cylindrical body
32 shell
34, 34A tongue portion
38 metal plate
38A metal plate (second ground level conductor)
40 insulating layer
42 electrode
42a ground electrode
42b high-speed transmission electrode
42c high-speed reception electrode
44 mounting terminal
44a ground terminal
46 notch
48a first portion (first ground level conductor)
48b second portion (second ground level conductor)
50 pull-up resistor
52 capacitor
56 abnormality detection electrode (first ground level conductor)
58 contact portion
60 abnormality detection terminal

What is claimed is:

1. A connector-board assembly comprising:
a receptacle connector; and
a board on which the receptacle connector is mounted,
wherein the receptacle connector has a tongue portion having electrodes at an approximately intermediate portion in a vertical direction of a plug insertion hollow portion,
wherein the tongue portion has a first ground level conductor and a second ground level conductor which extend from a base end side toward an opening side of the receptacle connector and are electrically conductive to each other on the opening side,
wherein the first ground level conductor is connected to a signal input port of a detection determining unit in the board and connected to a power supply via a pull-up resistor, and
wherein the second ground level conductor is connected to the ground.

2. The connector-board assembly according to claim 1, wherein the tongue portion includes insulating layers provided above and below a metal plate and includes the electrodes provided on surfaces of the insulating layers, and
wherein the first ground level conductor and the second ground level conductor are formed to be separated by a slit-shaped notch formed in the metal plate.

3. The connector-board assembly according to claim 2, wherein when viewed in a surface normal direction of the tongue portion, the notch is provided to avoid overlapping with the highest speed signal line electrode among the electrodes.

4. The connector-board assembly according to claim 3, wherein the tongue portion includes a ground electrode provided adjacent to the highest speed signal line electrode, and
wherein when viewed in the surface normal direction of the tongue portion, the notch overlaps with the ground electrode along the highest speed signal line electrode.

5. The connector-board assembly according to claim 1, wherein the tongue portion includes insulating layers provided above and below a metal plate and includes the electrodes provided on surfaces of the insulating layers,
wherein the first ground level conductor is a ground electrode among the electrodes, and
wherein the second ground level conductor is the metal plate.

6. The connector-board assembly according to claim 1, wherein the first ground level conductor is thinner than the second ground level conductor.

7. An electronic apparatus comprising:
a receptacle connector; and
a board on which the receptacle connector is mounted,
wherein the receptacle connector has a tongue portion having electrodes at an approximately intermediate portion in a vertical direction of a plug insertion hollow portion,
wherein the tongue portion has a first ground level conductor and a second ground level conductor which extend from a base end side toward an opening side of the receptacle connector and are electrically conductive to each other on the opening side,
wherein the first ground level conductor is connected to a signal input port of a detection determining unit in the board and connected to a power supply via a pull-up resistor, and
wherein the second ground level conductor is connected to the ground on the board.
